(19) United States
(12) Patent Application Publication
(10) Pub. No.: US 2012/0060906 A1
(43) Pub. Date: Mar. 15, 2012

(54) PHOTOVOLTAIC DEVICE INCLUDING FLEXIBLE OR INFLEXIBLE SUBSTRATE AND METHOD FOR MANUFACTURING THE SAME

(76) Inventor: Seung-Yeop Myong, Seoul (KR)

(21) Appl. No.: 13/048,403

(22) Filed: Mar. 15, 2011

(30) Foreign Application Priority Data
Mar. 15, 2010 (KR) 10-2010-0022647

(51) Int. Cl. H01L 31/06; H01L 31/18

(52) U.S. Cl. 136/255; 438/87; 257/E31.061

(57) ABSTRACT

Disclosed is a method for manufacturing a photovoltaic device including a substrate; a first electrode and a second electrode which are placed over the substrate; a first conductive semiconductor layer, an intrinsic semiconductor layer including a first sub-layer and a second sub-layer, and a second conductive semiconductor layer, which are placed between the first electrode and the second electrode. The method comprising: forming the first sub-layer having a first crystal volume fraction in an ‘i’-th process chamber group (‘i’ is a natural number equal to or greater than 1) among a plurality of process chamber groups; and forming the second sub-layer in an ‘i+1’-th process chamber group among the plurality of the process chamber groups, the second sub-layer contacting with the first sub-layer, including crystalline silicon grains and having a second crystal volume fraction greater than the first crystal volume fraction.

### CROSS-REFERENCE TO RELATED APPLICATION

This application claims priority under 35 U.S.C. §119 to Korean Patent Application No. 10-2010-0022647 filed on Mar. 15, 2010, the entirety of which is hereby incorporated by reference.

### FIELD OF THE INVENTION

The present invention relates to a photovoltaic device including a flexible substrate or an inflexible substrate and a method for manufacturing the same.

### BACKGROUND OF THE INVENTION

Recently, as existing energy resources like oil and coal and the like are expected to be exhausted, much attention is increasingly paid to alternative energy sources which can be used in place of the existing energy sources. As an alternative energy source, sunlight energy is abundant and has no environmental pollution. Therefore, more and more attention is paid to the sunlight energy.

A photovoltaic device, that is, a solar cell directly converts sunlight energy into electrical energy. The photovoltaic device mainly uses photovoltaic effect of semiconductor junction. In other words, when light is incident on and absorbed by a semiconductor p-i-n junction doped with p-type impurity and n-type impurity respectively, light energy generates electrons and holes within the semiconductor and the electrons and the holes are separated from each other by an internal field. As a result, a photo-electro motive force is generated between both ends of the p-i-n junction. Here, when electrodes are formed at both ends of the junction and connected with wires, electric current flows externally through the electrodes and the wires.

In order that the existing energy sources such as oil is substituted with the sunlight energy source, it is necessary to provide a photovoltaic device with a low degradation rate and a high stabilized efficiency.

### SUMMARY OF THE INVENTION

One aspect of the present invention is a method for manufacturing a photovoltaic device including a substrate; a first electrode and a second electrode which are placed over the substrate; a first conductive semiconductor layer, an intrinsic semiconductor layer including a first sub-layer and a second sub-layer, and a second conductive semiconductor layer, which are placed between the first electrode and the second electrode. The method comprising: forming the first sub-layer having a first crystal volume fraction in an ‘i’-th process chamber group (‘i’ is a natural number equal to or greater than 1) among a plurality of process chamber groups; and forming the second sub-layer in an ‘i+1’-th process chamber group among the plurality of the process chamber groups, the second sub-layer contacting with the first sub-layer, including crystalline silicon grains and having a second crystal volume fraction greater than the first crystal volume fraction.

Another aspect of the present invention is a method for manufacturing a photovoltaic device including a substrate; a first electrode and a second electrode which are placed over the substrate; a first conductive semiconductor layer, an intrinsic semiconductor layer and a second conductive semiconductor layer, which are placed between the first electrode and the second electrode. The method comprising: maintaining constant, in an ‘i’-th process chamber group (‘i’ is a natural number equal to or greater than 1) among a plurality of process chamber groups, a first process condition for forming a first sub-layer of the intrinsic semiconductor layer during the formation of the first sub-layer; and maintaining constant, in an ‘i+1’-th process chamber group among the plurality of the process chamber groups, a second process condition different from the first process condition and for forming a second sub-layer of the intrinsic semiconductor layer during the formation of the second sub-layer contacting with the first sub-layer and including crystalline silicon grains.

Further another aspect of the present invention is a photovoltaic device of the present invention. The photovoltaic device includes: a substrate; a first electrode and second electrode which are placed over the substrate; and a plurality of photoelectric conversion layers placed between the first electrode and the second electrode, wherein an intrinsic semiconductor layer of a photoelectric conversion layer that is the closest to a light incident side among the plurality of the photoelectric conversion layers comprises a first sub-layer composed of amorphous silicon based material and a second sub-layer including crystalline silicon grains.

Yet another aspect of the present invention is a photovoltaic device of the present invention. The photovoltaic device includes: a substrate; a first electrode and second electrode which are placed over the substrate; and a plurality of photoelectric conversion layers placed between the first electrode and the second electrode, wherein an intrinsic semiconductor layer of a photoelectric conversion layer, which is adjacent to a photoelectric conversion layer on which light is incident prior to the photoelectric conversion layer among the plurality of the photoelectric conversion layers, comprises a first sub-layer including germanium and a second sub-layer which is composed of amorphous silicon or has a crystal volume fraction greater than a crystal volume fraction of the first sub-layer.

### BRIEF DESCRIPTION OF THE DRAWINGS

FIGS. 1a to 1c show a system that can be used to manufacture a photovoltaic device according to an embodiment of the present invention.

FIG. 2 shows an intrinsic semiconductor layer manufactured according to the embodiment of the present invention.

FIG. 3 shows flow rate changes of hydrogen gas and silicon-containing gas.

FIG. 4 shows frequency changes of voltage supplied to a manufacturing system of the photovoltaic device.

FIG. 5 shows temperature changes of the manufacturing system of the photovoltaic device.

FIG. 6 shows plasma discharge power changes of the manufacturing system of the photovoltaic device.

FIGS. 7a to 7e show flow rate changes of gas including a non-silicon element.

FIGS. 8a and 8b show a photovoltaic device according to the embodiment of the present invention.

FIG. 9 shows an intrinsic semiconductor layer composed of only proto-crystalline silicon.

FIG. 10 shows a table arranging sub-layers of the photovoltaic device according to the embodiment of the present invention.

### DETAILED DESCRIPTION

A method for manufacturing a photovoltaic device according to an embodiment of the present invention will be described in detail with reference to the drawings.

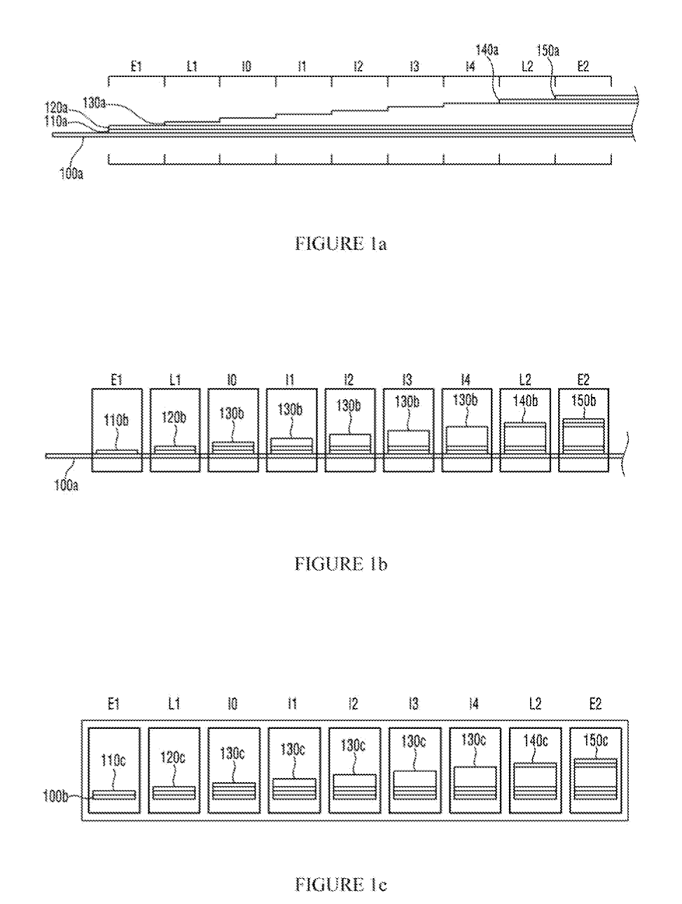

FIGS. 1a to 1c show a system that can be used to manufacture the photovoltaic device according to the embodiment of the present invention.

FIG. 1a shows a roll-to-roll type manufacturing system of a photovoltaic device. FIG. 1b shows a stepping roll type manufacturing system of the photovoltaic device. FIG. 1c shows an in-line type manufacturing system of the photovoltaic device.

As shown in FIGS. 1a to 1c, each system includes a plurality of process chamber groups I0 to I4 for forming an intrinsic semiconductor layer. FIGS. 1a to 1c show that the process chamber group includes one process chamber. However, two or more process chambers may be included. The number of the process chambers included in one process chamber group may be the same as or different from the number of the process chambers included in other process chamber groups.

Intrinsic semiconductor layer 130a to 130c of the photovoltaic devices are thicker than first conductive semiconductor layer 120a to 120c or second conductive semiconductor layer 140a to 140c, each of which corresponds to a p-type semiconductor layer and an n-type semiconductor layer, respectively. Therefore, the photovoltaic device manufacturing system includes a larger number of the process chambers than the number of the process chambers L1 and L2 that are used to form the first conductive semiconductor layer 120a to 120c or the second conductive semiconductor layer 140a to 140c.

The roll-to-roll type manufacturing system or the stepping roll type manufacturing system of the photovoltaic device can be used to form a photovoltaic device including a flexible substrate 100a such as a metal foil or a polymer substrate. In the roll-to-roll type manufacturing system or the stepping roll type manufacturing system, the first conductive semiconductor layer, the intrinsic semiconductor layer and the second conductive semiconductor layer are formed on the flexible substrate 100a in the process chambers.

For example, when group III doping gas, hydrogen gas and silicon-containing gas like silane gas are introduced into the process chamber L1, a p-type semiconductor layer is formed on the substrate 100a. When group V doping gas, hydrogen gas and silicon-containing gas are introduced into the process chamber L1, an n-type semiconductor layer is formed on the substrate 100a. Hydrogen gas and silicon-containing gas are introduced into the process chamber groups I0 to I4 for forming the intrinsic semiconductor layers 130a and 130b. When a p-type semiconductor layer is formed in the process chamber L1, an n-type semiconductor layer is formed in the process chamber L2. When an n-type semiconductor layer is formed in the process chamber L1, a p-type semiconductor layer is formed in the process chamber L2.

In the roll-to-roll type manufacturing system, while a roll (not shown) continuously rotates, the substrate 100a rolled in a roll passes by the insides of the process chambers. As a result, a first electrode 110a, a first conductive semiconductor layer 120a, an intrinsic semiconductor layer 130a, a second conductive semiconductor layer 140a and a second electrode 150a are continuously formed on the substrate 100a. In the roll-to-roll type manufacturing system, since the process chambers may not be completely separated from each other, the sub-layers of the intrinsic semiconductor layer 130a are apt to have a multi-layer structure having continuously changing interface properties.

In the stepping roll type manufacturing system, the roll rotates and stops repetitively. While the roll rotates, a gate (not shown) or a top plate (not shown) of each of the process chambers is opened and the substrate 100a moves. While the roll stops, the gate or top plate is closed and the corresponding layers are formed in each process chamber.

As shown in FIG. 1c, in the in-line type manufacturing system, an inflexible substrate 100b like glass is transferred to the process chambers by a transfer means (not shown). A first electrode 110c, a first conductive semiconductor layer 120c, an intrinsic semiconductor layer 130c, a second conductive semiconductor layer 140c and a second electrode 150c are formed in the process chambers.

In the stepping roll type manufacturing system or in the in-line type manufacturing system, since the process chambers are completely separated from each other, the sub-layers of the intrinsic semiconductor layer 130a has a super lattice structure having discontinuously changing interface properties.

As shown in FIGS. 1a to 1c, while the substrate 100a and 100b passes by the process chamber groups I0 to I4, the thickness of the intrinsic semiconductor layer 130a to 130c is increased.

The manufacturing systems described above include process chambers E1 and E2 which are used to form the first electrode 110a to 110c and the second electrode 150a to 150c respectively. However, the manufacturing systems described above may not have the process chambers E1 and E2 for forming the electrodes.

In the manufacturing systems of FIGS. 1a, 1b and 1c, the process chamber E1 and the process chamber E2 are used to form the first electrode 110a to 110c and the second electrode 150a to 150c respectively. The first electrode 110a to 110c and the second electrode 150a to 150c are placed on the substrate 100a and 100b. The first conductive semiconductor layer 120a to 120c, the intrinsic semiconductor layer 130a to 130c and the second conductive semiconductor layer 140a to 140c are placed between the first electrode 110a to 110c and the second electrode 150a to 150c.

As such, various types of substrates can be applied to the photovoltaic device according to the embodiment of the present invention.

A vacuum pump is operated so as to remove impurities inside the process chamber groups I0 to I4. The impurities inside the process chambers E1, L1, I0 to I4, L2 and E2 are hereby removed.

When the insides of the process chamber groups I0 to I4 actually enter a vacuum state, hydrogen gas and silicon-containing gas are introduced into the process chamber groups I0 to I4 through a mass flow controller, or not only the hydrogen gas and silicon-containing gas but also gas including non-silicon element is introduced into the process chamber groups I0 to I4 through a mass flow controller. Here, the mass flow controller controls an angle valve in such a manner that the flow rate of the gas is maintained constant, and the pressures of the process chamber groups I0 to I4 are controlled respectively to be maintained constant according to the angle of the angle valve.

The manufacturing system shown in FIGS. 1a to 1c can used to produce a single junction photovoltaic device including the first conductive semiconductor layer 120a to 120c, the intrinsic semiconductor layer 130a to 130c and the second conductive semiconductor layer 140a to 140c, and can also be used to produce a multi junction tandem photovoltaic device by further including separate process chambers that form first conductive semiconductor layers, intrinsic semiconductor layers and second conductive semiconductor layers.

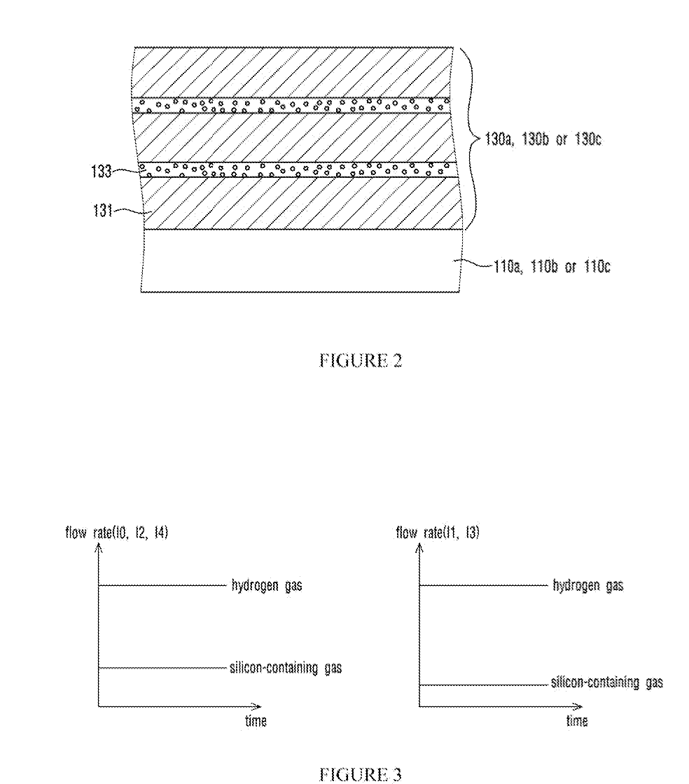

The intrinsic semiconductor layer 130a to 130c of the photovoltaic device manufactured according to the embodiment of the present invention include, as shown in FIG. 2, a first sub-layer 131 having no crystalline silicon grains and a second sub-layer 133 having crystalline silicon grains. The crystalline silicon grain will be described in detail later.

Meanwhile, an integration process, such as a laser scribing process, connecting adjacent cells in series may be performed between the process chambers, or may be performed after the second electrode is formed. Further, the integration process may be formed after the first electrode is formed, or may be formed after the second conductive semiconductor layer is formed and before the second electrode is formed. The integration process may be also formed between the roll-to-roll type manufacturing systems as well.

The method for manufacturing the photovoltaic device according to the embodiment of the present invention includes a step in which the first sub-layer 131 of the intrinsic semiconductor layer 130a to 130c, which has a first crystal volume fraction, is formed in the ‘i’-th process chamber group (‘i’ is a natural number equal to or greater than 1) among the plurality of the process chamber groups, and a step in which the second sub-layer 133 of the intrinsic semiconductor layer 130a to 130c, which contacts with the first sub-layer 131, includes crystalline silicon mains and has a second crystal volume fraction greater than the first crystal volume fraction, is formed in the ‘i+1’-th process chamber group among the plurality of the process chamber groups.)

Accordingly, the first sub-layer 131 and the second sub-layer 133 are formed in an alternating manner. The crystal volume fraction is a ratio of a volume occupied by crystal to the unit volume. Since the second sub-layer 133 includes the crystalline silicon grains, the crystal volume fraction of the second sub-layer 133 is greater than that of the first sub-layer 131.

That is, the method for manufacturing the photovoltaic device according to the embodiment of the present invention includes a step in which a first process condition for forming the first sub-layer 131 is maintained in the ‘i’-th process chamber group (‘i’ is a natural number equal to or greater than 1) among the plurality of the process chamber groups for a time during which the first sub-layer 131 of the intrinsic semiconductor layer 130a to 130c including amorphous semiconductor material is formed, and includes a step in which a second process condition different from the first process condition is maintained in the ‘i+1’-th process chamber group for a time during which the second sub-layer 133 including the crystalline silicon grains and contacting with the first sub-layer is formed.

In order to form the first sub-layers 131 and the second sub-layers 133 of the intrinsic semiconductor layer 130a to 130c, the process conditions of the adjacent process chamber groups among the process chamber groups I0 to I4 for forming the intrinsic semiconductor layer 130a to 130c may be different from each other.

A process condition affecting the formation of the crystalline silicon grain includes a hydrogen dilution ratio of silicon-containing gas and hydrogen gas introduced into the process chamber group, the frequency of voltage supplied to the process chamber group, the temperature within the process chamber group, and the flow rate of gas including non-silicon element. Besides, process pressures and plasma discharge powers within the process chambers may affect the formation of the crystalline silicon grain as well.

The hydrogen dilution ratio is a ratio of the flow rate of hydrogen gas to the flow rate of silicon-containing gas. When the hydrogen dilution ratio increases, the crystalline silicon grain can be formed within the second sub-layer 133. That is, the hydrogen dilution ratio of hydrogen gas and silicon-containing gas introduced into the ‘i’-th process chamber group is smaller than the hydrogen dilution ratio of hydrogen gas and silicon-containing gas introduced into the ‘i+1’-th process chamber group. As a result, the second sub-layer 133 including the crystalline silicon grains are formed in the ‘1+1’-th process chamber group. Here, the hydrogen dilution ratio of hydrogen gas and silicon-containing gas introduced into the ‘i’-th process chamber group can be maintained constant for a time during which the first sub-layer 131 is formed. The hydrogen dilution ratio of hydrogen gas and silicon-containing gas introduced into the ‘i+1’-th process chamber group can be also maintained constant for a time during which the second sub-layer 133 is formed.

For example, as shown in FIG. 3, the hydrogen dilution ratios of the gases introduced into the first, the third and the fifth process chamber groups I0, I2 and I4 are the same as each other. The hydrogen dilution ratios of the second and the fourth process chamber groups I1 and I3 are greater than those of the adjacent process chamber groups I0, I2 and I4. As a result, the intrinsic semiconductor layer 130a to 130c includes five sub-layers. The first sub-layer 131 and the second sub-layer 133 including the crystalline silicon grains are alternately formed.

The hydrogen dilution ratio of each of the process chamber groups I0, I1, I2, I3 and I4 is maintained constant for a time during which a sub-layer is formed. The hydrogen dilution ratios of the two adjacent process chamber groups are different from each other. Therefore, since the flow rates of the gases introduced into each of the process chamber groups I0, I1, I2, I3 and I4 is maintained constant for a time during which the sub-layer is formed, it is possible to prevent powder production, film quality degradation and thickness uniformity degradation caused by the gas flow rate change, and to easily control the process chambers.

The flow rate of hydrogen gas introduced into the process chamber group is less than that of the silicon-containing gas introduced into the process chamber group, so that it is more difficult to control the flow rate of hydrogen gas than to control the flow rate of the silicon-containing gas. Therefore, the flow rates of hydrogen gas supplied to the ‘i’-th and the ‘i+1’-th process chamber groups may be constant. For example, in the embodiment of the present invention, the flow rates of hydrogen gas introduced into each of the process chamber groups I0, I1, I2, I3 and I4 may be the same as each other and the flow rates of silicon-containing gas introduced into the adjacent process chamber groups may be different from each other.

The first sub-layer 131 and the second sub-layer 133 may be formed by not only the hydrogen dilution ratio difference but the process pressure difference between the process chambers. In other words, the hydrogen dilution ratio of gases introduced into the ‘i’-th process chamber group is less than the hydrogen dilution ratio of gases introduced into the ‘i+1’-th process chamber group, and the process pressure within the ‘i’-th process chamber group may be greater than the process pressure within the ‘i+1’-th process chamber group.

Accordingly, the first sub-layer 131 is formed in the ‘i’-th process chamber group. The second sub-layer 133 is formed in the ‘i+1’-th process chamber group. When the process pressure of the process chamber increases, the flow velocity of the gas introduced into the process chamber increases. Therefore, deposition rate increases, so that the first sub-layer 131 is formed. When the process pressure of the process chamber decreases, the flow velocity of the gas introduced into the process chamber decreases. Therefore, deposition rate decreases, so that the second sub-layer 133 is formed.

When gases are introduced into the process chamber groups I0 to I4 and a voltage is supplied, an electric potential difference is generated between a plate on which the substrate 100a and 100b is placed and the electrode of the process chamber groups I0 to I4, so that the gases become in a plasma state. Regarding the frequency of the voltage supplied to the process chamber group, when the frequency increases, the crystalline silicon grain is formed in the second sub-layer 133. That is, the higher the frequency is, the higher the plasma density within the process chamber becomes, so that an electron temperature decreases. As a result, ion damage at a thin film surface or interface is reduced, which makes crystal easily grow.

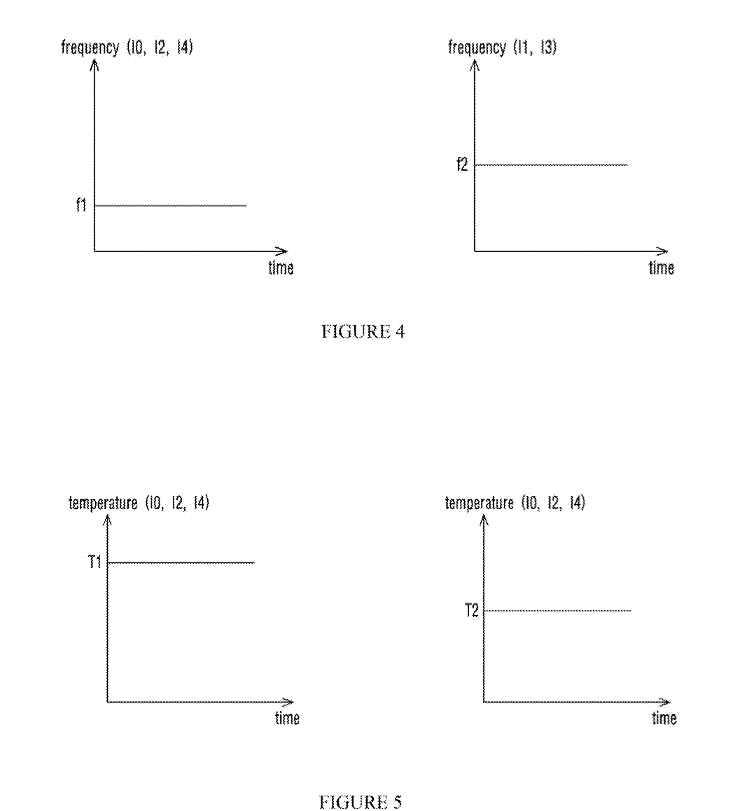

That is, the frequency of the voltage supplied to the ‘i’-th process chamber group may be lower than the frequency of the voltage supplied to the ‘i+1’-th process chamber group. Accordingly, the first sub-layer 131 is formed in the ‘i’-th process chamber group. The second sub-layer 133 is formed in the ‘i+1’-th process chamber group. For example, as shown in FIG. 4, the frequencies f1 of the voltages supplied to the first, the third and the fifth process chamber groups I0, I2 and I4 are the same as each other. The frequencies f2 of the voltages supplied to the second and the fourth process chamber groups I1 and I3 are higher than the frequencies f1 of the adjacent process chamber groups I0, I2 and I4. Therefore, the intrinsic semiconductor layer 130a to 130c includes five sub-layers. The first sub-layer 131 and the second sub-layer 133 including the crystalline silicon grains are alternately formed.

The frequency of each of the process chamber groups I0, I1, I2, I3 and I4 is maintained constant for a time during which a sub-layer is formed. The frequencies f1 and f2 of the adjacent process chamber groups are different from each other. Therefore, since the frequency of the voltage supplied to each of the process chamber groups I0, I1, I2, I3 and I4 is maintained constant for a time during which the sub-layer is formed, it is possible to prevent film quality degradation caused by the frequency variation and to easily control the process chambers.

In the embodiment of the present invention, the frequency f1 for forming the first sub-layer 131 may be equal to or higher than 13.56 MHz. The second frequency f2 higher than the frequency f1 may be equal to or higher than 27.12 MHz.

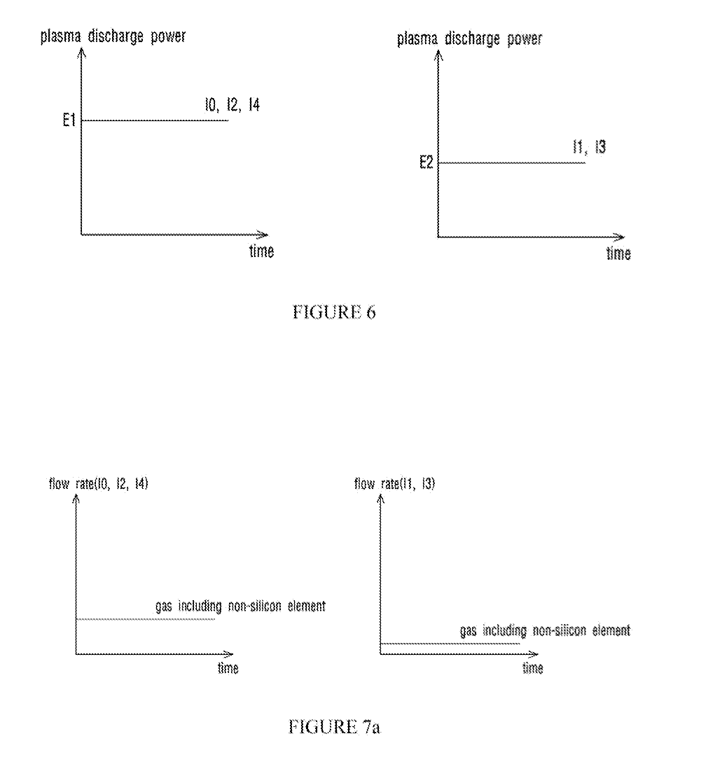

Meanwhile, when the temperature of the process chamber group rises, the deposition rate becomes higher, and then the first sub-layer 131 including amorphous silicon is formed. When the temperature of the process chamber group falls, the deposition rate becomes lower, and then the crystalline silicon grain is formed in the second sub-layer 133. That is, the temperature of the ‘i’-th process chamber group is higher than the temperature of the ‘i+1’-th process chamber group. For example, as shown in FIG. 5, the temperatures T1 of the first, the third and the fifth process chamber groups I0, I2 and I4 are the same as each other. The temperatures T2 of the second and the fourth process chamber groups I1 and I3 are lower than the temperature T1 of the adjacent process chamber groups I0, I2 and I4. Therefore, the intrinsic semiconductor layer 130a to 130c includes five sub-layers. The first sub-layer 131 including amorphous silicon and the second sub-layer 133 including the crystalline silicon grains are alternately formed.

Here, when the temperature of the process chamber group is equal to or higher than a phase transition boundary temperature, the first sub-layer 131 is formed, and when the temperature of the process chamber group is lower than the phase transition boundary temperature, the second sub-layer 133 is formed. The phase transition boundary temperature corresponds to a temperature at which the amorphous silicon is crystallized.

The temperature of each of the process chamber groups I0 to I4 is maintained constant for a time during which a sub-layer is formed. The temperatures T1 and T2 of the adjacent process chamber groups are different from each other. Therefore, since the temperature of each of the process chamber groups I0 to I4 is maintained constant for a time during which the sub-layer is formed, it is possible to prevent film quality degradation caused by the temperature variation and to easily control the process chambers.

When a plasma discharge power supplied to the process chamber group increases, the deposition rate becomes higher. The first sub-layer 131 having a low crystal volume fraction is formed in a process chamber group having a high plasma discharge power. The second sub-layer 133 having a high crystal volume fraction and including the crystal silicon grains is formed in a process chamber group having a low plasma discharge power. The plasma discharge power is supplied so as to make the gas introduced into to the process chamber group enter the plasma state, and may be a voltage supplied to the process chamber group.

That is, the plasma discharge power of the ‘i’-th process chamber group may be higher than that of the ‘i+1’-th process chamber group. For example, as shown in FIG. 6, the plasma discharge powers E1 of the first, the third and the fifth process chamber groups I0, I2 and I4 are the same as each other. The plasma discharge powers E2 of the second and the fourth process chamber groups I1 and I3 are lower than the plasma discharge powers E1 of the adjacent process chamber groups I0, I2 and I4. Therefore, the intrinsic semiconductor layer 130a to 130c includes five sub-layers. The first sub-layer 131 including amorphous silicon and the second sub-layer 133 including the crystalline silicon grains are alternately formed.

In addition, when the flow rate of gas including non-silicon element like oxygen; carbon, nitrogen and germanium is changed, the crystalline silicon grain can be formed. The gas including non-silicon element prevents the crystallization of amorphous silicon. Therefore, as the flow rate of gas including non-silicon element increases, the crystallinity decreases and the deposition rate decreases. As the flow rate of gas including non-silicon element is decreased, the crystallinity and the deposition rate increase.

That is, the flow rate of gas including non-silicon element, which is introduced into the ‘i’-th process chamber group, may be greater than the flow rate of gas including non-silicon element, which is introduced into the ‘i+1’-th process chamber group. The second sub-layer 133 including the crystalline silicon grains is hereby formed in the ‘i+1’-th process chamber group.

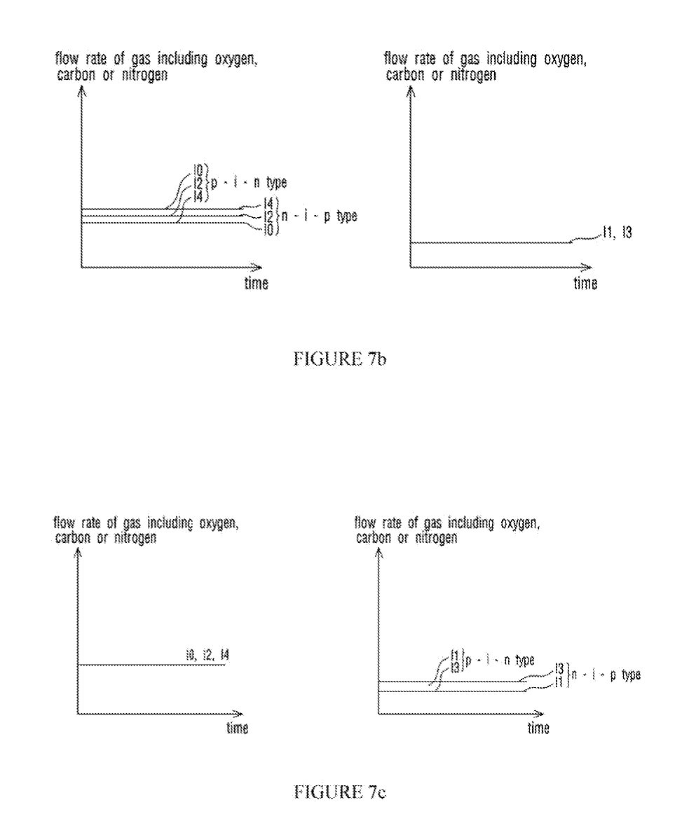

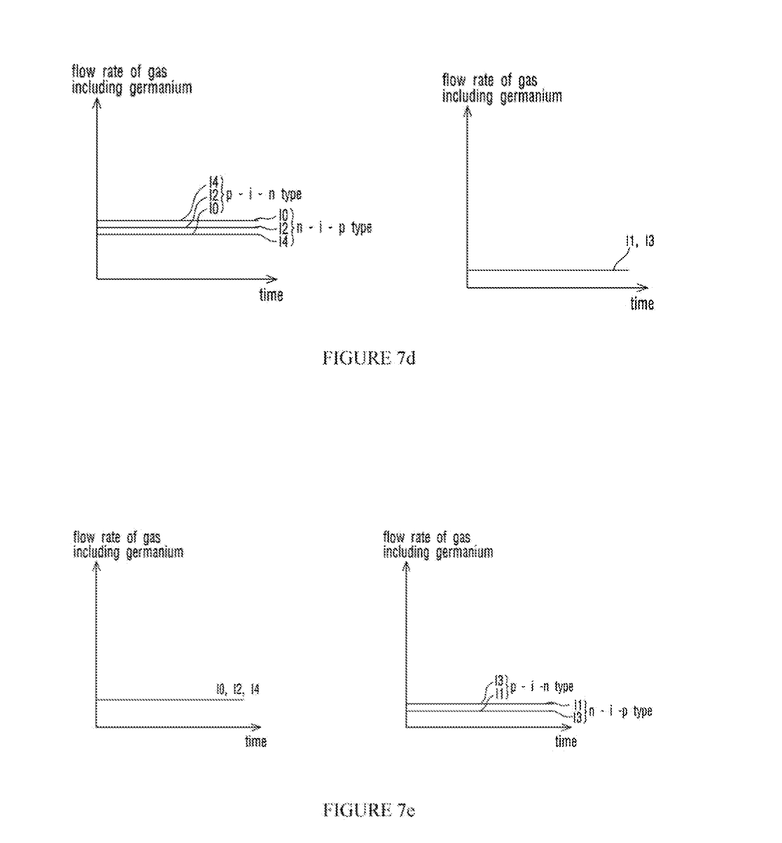

For example, as shown in FIG. 7a, the flow rate of the gas including non-silicon element, which is introduced into each of the first, third and fifth process chamber groups I0, I2 and I4, is constant. The flow rate of the gas including non-silicon element, which is introduced into each of the second and the fourth process chamber groups I1 and I3, is less than the flow rate of the adjacent process chamber groups I0, I2 and I4. Therefore, the intrinsic semiconductor layer 130a to 130c includes five sub-layers. The first sub-layer 131 and the second sub-layer 133 including the crystalline silicon grains are alternately formed.

The flow rate of the gas including non-silicon element, which is introduced into each of the process chamber groups I0 to I4, is maintained constant for a time during which a sub-layer is formed. The flow rates of the adjacent process chamber groups are different from each other. Therefore, since the flow rate of each of the process chamber groups I0 to I4 is maintained constant for a time during which the sub-layer is formed, it is possible to prevent film quality degradation caused by the flow rate change and to easily control the process chambers.

Next, the flow rate change of the gas including non-silicon element will be described with reference to FIGS. 7b to 7e.

First, described will be the flow rate change of gas used to manufacture an n-i-p type photovoltaic device having an n-type semiconductor layer, an intrinsic semiconductor layer and a p-type semiconductor layer, which are sequentially stacked on the substrate 100a and 100b.

When gas including non-silicon element includes oxygen, carbon or nitrogen, the flow rate of the gas including non-silicon element such as oxygen, carbon or nitrogen, which is respectively introduced into the ‘i’-th process chamber group and the ‘i+2’-th process chamber group in which the first sub-layer 131 is formed, is constant. The flow rate of the gas including non-silicon element, which is introduced into the ‘i’-th process chamber group is less than the flow rate of the gas including non-silicon element, which is introduced into the ‘i+2’-th process chamber group.

Here, the flow rate of the gas including non-silicon element, which is introduced into the process chamber groups in which the second sub-layer 133 is formed, is less than the flow rate of the gas including non-silicon element, which is introduced into the process chamber groups in which the first sub-layer 131 is formed.

For example, as shown in FIG. 7b, the flow rate of the gas including oxygen, carbon or nitrogen, which is respectively introduced into the process chamber groups I0, I2 and I4 in which the first sub-layer 131 is formed, is constant. The flow rate of the gas including oxygen, carbon or nitrogen, which is introduced into the process chamber group I0 is less than the flow rate of the gas including oxygen, carbon or nitrogen, which is introduced into the process chamber group I2. The flow rate of the gas including oxygen, carbon or nitrogen, which is introduced into the process chamber group I2 is less than the flow rate of the gas including oxygen, carbon or nitrogen, which is introduced into the process chamber group I4.

Here, the flow rate of the gas including oxygen, carbon or nitrogen, which is introduced into the process chamber groups I1 and I3 in which the second sub-layer 133 is formed is less than the flow rate of the gas including oxygen, carbon or nitrogen, which is introduced into the process chamber groups I0, I2 and I4 in which the first sub-layer 131 is formed.

When gas including non-silicon element includes oxygen, carbon or nitrogen, unlike the flow rate change shown in FIG. 7b, the flow rate of the gas including non-silicon element such as oxygen, carbon or nitrogen, which is respectively introduced into the ‘i+1’-th process chamber group and the ‘i+3’-th process chamber group in which the second sub-layer 133 is formed is, constant. The flow rate of the gas including non-silicon element, which is introduced into the ‘i+1’-th process chamber group is less than the flow rate of the gas including non-silicon element, which is introduced into the ‘i+3’-th process chamber group.

Here, the flow rates of the gas including non-silicon element, which is introduced into the ‘i+1’-th and the ‘i+3’ process chamber groups, are less than the flow rate of the gas including non-silicon element, which is introduced into the process chamber groups in which the first sub-layer 131 is formed.

For example, as shown in FIG. 7c, the flow rate of the gas including oxygen, carbon or nitrogen, which is respectively introduced into the process chamber groups I1 and I3 in which the second sub-layer 133 is formed, is constant. The flow rate of the gas including oxygen, carbon or nitrogen, which is introduced into the process chamber group I1 is less than the flow rate of the gas including oxygen, carbon or nitrogen, which is introduced into the process chamber group I3. Here, the flow rates of the gas including oxygen, carbon or nitrogen, which are introduced into the process chamber groups I1 and I3 in which the second sub-layer 133 is formed are less than the flow rate of the gas including oxygen, carbon or nitrogen, which is introduced into the process chamber groups I0, I2 and I4 in which the first sub-layer 131 is formed.

When the gas including non-silicon element includes germanium, the flow rate change of the gas including germanium may be different from those described in FIGS. 7b and 7c.

That is, when the gas includes germanium, the flow rate of the gas including germanium, which is respectively introduced into the ‘i’-th process chamber group and the ‘i+2’-th process chamber group in which the first sub-layer 131 is formed, is constant. The flow rate of the gas including germanium, which is introduced into the ‘i’-th process chamber group is greater than the flow rate of the gas including germanium, which is introduced into the ‘i+2’-th process chamber group.

Here, the flow rate of the gas including germanium, which is introduced into the process chamber groups in which the second sub-layer 133 is formed, is less than the flow rates of the gas including germanium, which are introduced into the process chamber groups in which the first sub-layer 131 is formed.

For example, as shown in FIG. 7d, the flow rate of the gas including germanium, which is respectively introduced into of the process chamber groups I0, I2 and I4 in which the first sub-layer 131 is formed, is constant. The flow rate of the gas including germanium, which is introduced into the process chamber group I0 is greater than the flow rate of the gas including germanium, which is introduced into the process chamber group I2. The flow rate of the gas including germanium, which is introduced into the process chamber group I2 is greater than the flow rate of the gas including germanium, which is introduced into the process chamber group I4. Here, the flow rate of the gas including germanium, which is introduced into the process chamber groups I1 and I3 in which the second sub-layer 133 is formed is less than the flow rates of the gas including germanium, which are introduced into the process chamber groups I0, I2 and I4 in which the first sub-layer 131 is formed.

Meanwhile, the flow rate of the gas including germanium, which is respectively introduced into the ‘i+1’-th process chamber group and the ‘i+3’-th process chamber group in which the second sub-layer 133 is formed, is constant. The flow rate of the gas including germanium, which is introduced into the ‘i+1’-th process chamber group is greater than the flow rate of the gas including germanium, which is introduced into the ‘i+3’-th process chamber group.

Here, the flow rates of the gas including germanium, which are introduced into the process chamber groups in which the second sub-layer 133 is formed, are less than the flow rate of the gas including germanium, which is introduced into the process chamber groups in which the first sub-layer 131 is formed.

For example, as shown in FIG. 7e, the flow rate of the gas including germanium, which is respectively introduced into the process chamber groups I1 and I3 in which the second sub-layer 133 is formed, is constant. The flow rate of the gas including germanium, which is introduced into the process chamber group I1 is greater than the flow rate of the gas including germanium, which is introduced into the process chamber group I3. Here, the flow rates of the gas including germanium, which are introduced into the process chamber groups I1 and I3 in which the second sub-layer 133 is formed are less than the flow rate of the gas including germanium, which is introduced into the process chamber groups I0, I2 and I4 in which the first sub-layer 131 is formed. The following description includes the reason of the flow rates change in FIGS. 7b to 7e.

High energy density light with a short wavelength has a small penetration depth. The optical band gaps of the sub-layers should be large in order to absorb the light with a short wavelength having a high energy density. Therefore, sub-layers having relatively larger optical band gaps among the sub-layers are placed closer to a light incident side, so that it is possible to maximally absorb light with a short wavelength having a high energy density. When sub-layers having relatively smaller optical band gaps among the sub-layers are placed farther from the light incident side, it is possible to maximally absorb light with a wavelength other than the short wavelength.

Here, the more the flow rate of gas including non-silicon element such as oxygen, carbon or nitrogen is increased, the larger the optical band gap becomes. The less the flow rate of gas including non-silicon element such as germanium is, the larger the optical band gap becomes.

Regarding the n-i-p type photovoltaic device having the n-type semiconductor layer, the intrinsic semiconductor layer and the p-type semiconductor layer, which are sequentially stacked on the substrate 100a and 100b, light is incident through the p-type semiconductor layer opposite to the substrate 100a and 100b. Therefore, as shown in FIGS. 7b to 7e, the intrinsic semiconductor layer 130a, 130b and 130c is formed such that the closer the first sub-layer 131 and the second sub-layer 133 among the total sub-layers are to the p-type semiconductor layer, the larger the optical band gaps of the first sub-layer 131 and the second sub-layer 133 become. Next, described will be the flow rate change of gas used to manufacture a p-i-n type photovoltaic device having a p-type semiconductor layer, an intrinsic semiconductor layer and an n-type semiconductor layer, which are sequentially stacked on the substrate 100a and 100b.

Regarding the p-i-n type photovoltaic device having the p-type semiconductor layer, the intrinsic semiconductor layer and the n-type semiconductor layer which are sequentially stacked on the substrate 100a and 100b, light is incident through the p-type semiconductor layer of the side of the substrate 100a and 100b. Therefore, the intrinsic semiconductor layer 130a, 130b and 130c is formed such that the optical band gaps of the first sub-layer 131 and the second sub-layer 133 which are placed closer to the side of the substrate 100a and 100b among the total sub-layers become larger.

In other words, regarding the gas including non-silicon element such as oxygen, carbon or nitrogen, as shown in FIG. 7b, the flow rate of the gas supplied to the ‘i’-th process chamber group is greater than the flow rate of the gas supplied to the ‘i+2’-th process chamber group.

As shown in FIG. 7c, the flow rate of the gas including non-silicon element, which is introduced into the ‘i+1’-th process chamber group is greater than the flow rate of the gas supplied to the ‘i+3’-th process chamber group.

Here, the flow rate of the gas including oxygen, carbon or nitrogen, which is introduced into each process chamber group, is constant. The flow rate of the gas including oxygen, carbon or nitrogen, which is introduced into the process chamber groups in which the second sub-layer 133 is formed, is less than the flow rate of the gas including oxygen, carbon or nitrogen, which is introduced into the process chamber groups in which the first sub-layer 131 is formed.

Likewise, regarding the gas including non-silicon element such as germanium, as shown in FIG. 7d, the closer the sub-layers are to the p-type semiconductor layer placed on the side of the substrates 100a and 100b among the total sub-layers, the larger the optical band gap becomes. Therefore, the flow rate of the gas including non-silicon element such as germanium, which is introduced into the ‘i’-th process chamber group is less than the flow rate of the gas including non-silicon element such as germanium, which is introduced into the ‘i+2’-th process chamber group.

As shown in FIG. 7e, the flow rate of the gas including non-silicon element such as germanium, which is introduced into the ‘i+1’-th process chamber group is less than the flow rate of the gas including non-silicon element such as germanium, which is introduced into the ‘i+3’-th process chamber group.

Here, the flow rate of the gas including germanium introduced into each of the process chamber groups is constant. The flow rate of the gas including germanium, which is introduced into the process chamber groups in which the second sub-layer 133 is formed, is less than the flow rate of the gas including germanium, which is introduced into the process chamber groups in which the first sub-layer 131 is formed.

As described up to now, in the n-i-p type photovoltaic device or the p-i-n type photovoltaic device, the flow rate of the gas including oxygen, carbon or nitrogen, which is supplied to the process chamber groups in which the sub-layers relatively close to the p-type semiconductor layer on which light is incident are formed among the total sub-layers is greater than the flow rate the gas including oxygen, carbon or nitrogen, which is supplied to the process chamber groups in which the sub-layers relatively far from the p-type semiconductor layer on which light is incident are formed.

Regarding the gas including non-silicon element like germanium, as shown in FIGS. 7d and 7e, the flow rate of the gas including germanium, which is supplied to the process chamber groups in which the sub-layers relatively close to the p-type semiconductor layer are formed among the total sub-layers is less than the flow rate of the gas including germanium, which is supplied to the process chamber groups in which the sub-layers relatively far from the p-type semiconductor layer are formed.

Though flow rate graphs in FIGS. 7a, 7b and 7e show that the flow rates of gases including non-silicon element for forming the second sub-layer 133 are greater than 0, the flow rates of gases including non-silicon element for forming the second sub-layer 133 may be equal to 0. Though flow rate graphs in FIGS. 7c and 7e show that the minimum values of the flow rates of gases including non-silicon element for forming the second sub-layer 133 are greater than 0, the minimum values of the flow rates of gases including non-silicon element for forming the second sub-layer 133 may be equal to 0.

As shown in FIGS. 7b to 7e, the flow rate of the gas including non-silicon element, which is introduced into each of the process chamber groups in which the first sub-layer 131 and the second sub-layer 133 are formed, is constant. The closer it is to the light incident side, the larger the optical band gap of the first sub-layer 131 or the second sub-layer 133 may be.

For example, regarding the n-i-p type photovoltaic device, since light is incident from a side opposite to the substrate 100a and 100b, the closer it is to the side opposite to the substrate 100a and 100b, the larger the optical band gap of the first sub-layer 131 or the second sub-layer 133 is.

A photovoltaic device according to the manufacturing method described above will be described.

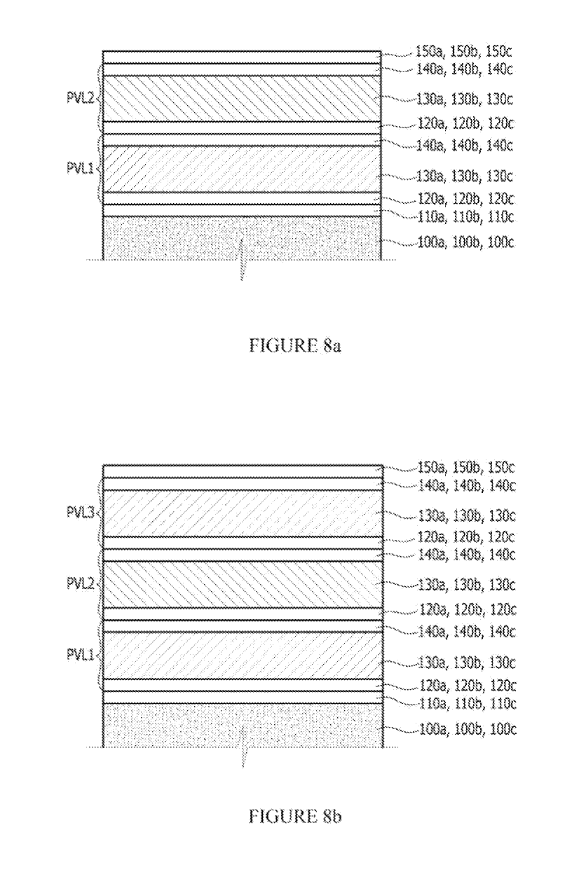

FIGS. 8a and 8b show a photovoltaic device according to the embodiment of the present invention. FIG. 8a shows a double junction tandem photovoltaic device. FIG. 8b shows a triple junction tandem photovoltaic device.

First, terms used in descriptions related to FIGS. 8a and 8b will be described. Hydrogenated amorphous silicon material may have no crystal structure or may have a microscopic regularity such as short-range-order (SRO) or medium-range-order (MRO).

Hydrogenated proto-crystalline silicon material is amorphous silicon which has been highly hydrogen diluted. The crystals of the hydrogenated proto-crystalline silicon material cannot be detected by Raman spectroscopy or X-ray diffraction (XRD). However, it can be found by transmission electron microscope (TEM) analysis that the hydrogenated proto-crystalline silicon material includes quantum dot-shaped crystalline silicon grains surrounded by good quality amorphous silicon material.

Hydrogenated nano-crystalline silicon material includes crystalline silicon grains surrounded by grain boundary or amorphous silicon material, and has a mixed phase structure formed by a mixture of crystalline silicon material and amorphous silicon material which are in the vicinity of a phase transition region.

As shown in FIGS. 8a and 8b, each of a plurality of photoelectric conversion layers PVL1, PVL2 and PVL3 includes a first conductive semiconductor layer 120a, 120b and 120c, an intrinsic semiconductor layer 130a, 130b and 130c, and a second conductive semiconductor layer 140a, 140b and 140c. The plurality of photoelectric conversion layers PVL1, PVL2 and PVL3 are located between a second electrode 150a, 150b and 150c and a first electrode 110a, 110b and 110c that are placed on substrate 100a, 100b and 100c.

Here, the intrinsic semiconductor layer of a photoelectric conversion layer that is the closest to the light incident side among the plurality of the photoelectric conversion layers PVL1, PVL2 and PVL3 includes both the first sub-layer 131 made of amorphous silicon material and the second sub-layer 133 including crystalline silicon grains.

That is, the intrinsic semiconductor layer of a top cell of a multi junction tandem photovoltaic device may be formed by introducing hydrogen gas and silane gas or by introducing not only the hydrogen gas and silane gas but also gas including non-silicon element such as oxygen, carbon or nitrogen.

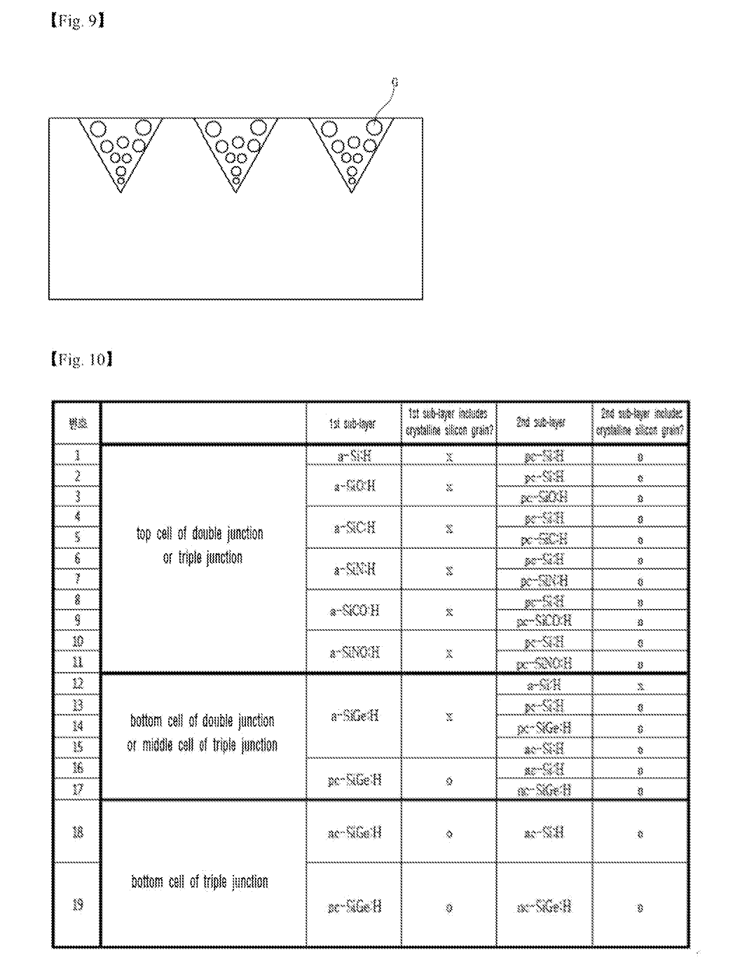

FIG. 10 shows the combinations of the first sub-layer 131 and the second sub-layer 133 which are numbered from 1 to 11. Through the combinations, it can be seen that the second sub-layer 133 is composed of proto-crystalline silicon material, and includes crystalline silicon grains surrounded by hydrogenated amorphous silicon material.

When hydrogen gas and silane gas are supplied to the process chamber groups I0 to 14, the first sub-layer 131 includes hydrogenated amorphous silicon (a-Si:H), and the second sub-layer 133 is composed of hydrogenated proto-crystalline silicon (pc-Si:H) including the crystalline silicon grains surrounded by the hydrogenated amorphous silicon.

When gas including non-silicon element like oxygen as well as hydrogen gas and silicon-containing gas are supplied, the first sub-layer 131 includes hydrogenated amorphous silicon oxide (i-a-SiO:H) and the second sub-layer 133 is composed of either hydrogenated proto-crystalline silicon (i-pc-Si:H) or hydrogenated proto-crystalline silicon oxide (i-pc-SiO:H), which includes the crystalline silicon grains surrounded by the hydrogenated amorphous silicon or the hydrogenated amorphous silicon oxide. As described above, the hydrogenated proto-crystalline silicon (i-pc-Si:H) is formed when the flow rate of oxygen for forming the second sub-layer 133 is 0.

When gas including non-silicon element like carbon as well as hydrogen gas and silicon-containing gas are supplied, the first sub-layer 131 includes hydrogenated amorphous silicon carbide (i-a-SiC:H) and the second sub-layer 133 is composed of either hydrogenated proto-crystalline silicon (i-pc-Si:H) or hydrogenated proto-crystalline silicon carbide (i-pc-SiC:H), which includes the crystalline silicon grains surrounded by the hydrogenated amorphous silicon or the hydrogenated amorphous silicon carbide.

When gas including non-silicon element like nitrogen as well as hydrogen gas and silicon-containing gas are supplied, the first sub-layer 131 includes hydrogenated amorphous silicon nitride (i-a-SiN:H) and the second sub-layer 133 is composed of either hydrogenated proto-crystalline silicon (i-pc-Si:H) or hydrogenated proto-crystalline silicon nitride (i-pc-SiN:H), which includes the crystalline silicon grains surrounded by the hydrogenated amorphous silicon or the hydrogenated amorphous silicon nitride.

When gas including carbon and oxygen as well as hydrogen gas and silicon-containing gas are supplied, the first sub-layer 131 includes hydrogenated amorphous silicon oxycarbide (i-a-SiCO:H) and the second sub-layer 133 is composed of either hydrogenated proto-crystalline silicon (i-pc-Si:H) or hydrogenated proto-crystalline silicon oxycarbide (pc-SiCO:H). The hydrogenated proto-crystalline silicon (i-pc-Si:H) includes the crystalline silicon grains surrounded by the hydrogenated amorphous silicon. The hydrogenated proto-crystalline silicon oxycarbide (pc-SiCO:H) includes the crystalline silicon grains surrounded by the hydrogenated amorphous silicon oxycarbide.

When gas including nitrogen and oxygen as well as hydrogen gas and silicon-containing gas are supplied, the first sub-layer 131 includes hydrogenated amorphous silicon oxynitride (i-a-SiNO:H) and the second sub-layer 133 is composed of either hydrogenated proto-crystalline silicon (i-pc-Si:H) or hydrogenated proto-crystalline silicon oxynitride (i-pc-SiNO:H). The hydrogenated proto-crystalline silicon (i-pc-Si:H) includes the crystalline silicon grains surrounded by the hydrogenated amorphous silicon. The hydrogenated proto-crystalline silicon oxynitride (i-pc-SiNO:H) includes the crystalline silicon grains surrounded by the hydrogenated amorphous silicon oxynitride.

As such, the intrinsic semiconductor layer formed by using the gas including non-silicon element such as hydrogen, carbon or nitrogen may be included in the top cell of the double junction tandem photovoltaic device or the triple junction tandem photovoltaic device. Here, the first sub-layer 131 includes hydrogenated amorphous silicon based material and the second sub-layer 133 comprises hydrogenated proto-crystalline silicon material including the crystalline silicon grains surrounded by the hydrogenated amorphous silicon based material.

Meanwhile, as shown in FIGS. 8a and 8b, the plurality of photoelectric conversion layers PVL1, PVL2 and PVL3 are located between the first electrode 110a, 110b and 110c and the second electrode 150a, 150b and 150c. Each of the plurality of photoelectric conversion layers PVL1, PVL2 and PVL3 includes the first conductive semiconductor layer 120a, 120b and 120c, the intrinsic semiconductor layer 130a, 130b and 130c, and the second conductive semiconductor layer 140a, 140b and 140c.

Here, the intrinsic semiconductor layer of a photoelectric conversion layer adjacent to the photoelectric conversion layer that is the closest to the light incident side among the plurality of the photoelectric conversion layers PVL1, PVL2 and PVL3 includes both the first sub-layer 131 including germanium and the second sub-layer 133 which is composed of amorphous silicon or has a crystal volume fraction greater than the crystal volume fraction of the first sub-layer 131.

That is, regarding the double junction tandem photovoltaic device, a bottom cell adjacent to the top cell on which light is first incident includes the first sub-layer 131 and the second sub-layer 133. Regarding the triple junction tandem photovoltaic device, either a middle cell adjacent to the top cell on which light is incident prior to the middle cell or the bottom cell adjacent to the middle cell on which light is incident to the bottom cell includes the first sub-layer 131 and the second sub-layer 133. Here, the first sub-layer 131 includes germanium. The second sub-layer 133 is composed of amorphous silicon or has a crystal volume fraction greater than the crystal volume fraction of the first sub-layer 131.

When gas including non-silicon element like germanium as well as hydrogen gas and silicon-containing gas are supplied, the first sub-layer 131 includes hydrogenated amorphous silicon germanium (i-a-SiGe:H). The second sub-layer 133 is composed of hydrogenated amorphous silicon (i-a-Si:H) or is composed of hydrogenated proto-crystalline silicon (i-pc-Si:H) including the crystalline silicon grains surrounded by the hydrogenated amorphous silicon. Also, the second sub-layer 133 is composed of hydrogenated proto-crystalline silicon germanium (i-pc-SiGe:H) including the crystalline silicon grains surrounded by the hydrogenated amorphous silicon germanium or is composed of hydrogenated nano-crystalline silicon (i-nc-Si:H) including the crystalline silicon grains surrounded by the amorphous silicon or grain boundary.

In addition, the first sub-layer 131 includes hydrogenated proto-crystalline silicon germanium (i-pc-SiGe:H). The second sub-layer 133 includes hydrogenated proto-crystalline silicon (i-pc-Si:H), hydrogenated nano-crystalline silicon (i-nc-Si:H) or hydrogenated nano-crystalline silicon germanium (i-nc-SiGe:H). The hydrogenated proto-crystalline silicon (i-pc-Si:H) includes the crystalline silicon grains surrounded by the hydrogenated amorphous silicon. The hydrogenated nano-crystalline silicon (i-nc-Si:H) includes the crystalline silicon grains surrounded by the hydrogenated amorphous silicon or grain boundary. The hydrogenated nano-crystalline silicon germanium (i-nc-SiGe:H) includes the crystalline silicon grains surrounded by the hydrogenated amorphous silicon germanium or grain boundary.

As such, the intrinsic semiconductor layer formed by using the gas including non-silicon element such as germanium may be included in the bottom cell of the double junction tandem photovoltaic device or in the middle cell of the triple junction tandem photovoltaic device. Here, the first sub-layer 131 includes hydrogenated amorphous silicon germanium or hydrogenated proto-crystalline silicon germanium. The second sub-layer 133 is composed of hydrogenated amorphous silicon, hydrogenated proto-crystalline silicon based material or hydrogenated nano-crystalline silicon based material.

Meanwhile, the bottom cell of the triple junction tandem photovoltaic device can be formed by using the gas including non-silicon element such as germanium. Here, the first sub-layer 131 includes hydrogenated proto-crystalline silicon based material or hydrogenated nano-crystalline silicon based material. The second sub-layer 133 includes hydrogenated nano-crystalline silicon based material.

For example, the first sub-layer 131 includes hydrogenated nano-crystalline silicon germanium (i-nc-SiGe:H), and the second sub-layer 133 is composed of hydrogenated nano-crystalline silicon (i-nc-Si:H) including the crystalline silicon grain surrounded by amorphous silicon or grain boundary. Besides, the first sub-layer 131 includes hydrogenated proto crystalline silicon germanium (i-pc-SiGe:H), and the second sub-layer 133 is composed of hydrogenated nano-crystalline silicon germanium (i-nc-SiGe:H) including the crystalline silicon grain surrounded by hydrogenated amorphous silicon germanium (i-a-SiGe:H) or grain boundary.

In the sub-layer combination numbered 12 in FIG. 10, since germanium prevents crystallization, the crystal volume fraction of the second sub-layer 133 is greater than the crystal volume fraction of the first sub-layer 131 including germanium.

In the sub-layer combinations numbered 13 and 14 in FIG. 10, the first sub-layer 131 is composed of an amorphous material and the second sub-layer 133 is composed of a proto-crystalline material. With regard to the proto-crystalline material, the crystalline silicon grain is detected by TEM measurement. Therefore, it can be seen that the crystal volume fraction of the second sub-layer 133 is greater than the crystal volume fraction of the first sub-layer 131.

In the sub-layer combinations numbered from 15 to 17 in FIG. 10, the first sub-layer 131 is composed of amorphous silicon germanium or proto-crystalline silicon germanium. The second sub-layer 133 is composed of mum-crystalline silicon or nano-crystalline silicon germanium. With regard to the nano-crystalline silicon material, the crystal volume fraction can be obtained through the following equation using the area of a component peak obtained by Raman spectroscopy.

crystal volume fraction(%)=[(A₅₁₀+A₅₂₀)/(A₄₈₀+A₅₁₀+A₅₂₀)]*100,

Here, Ai means an area of a component peak in the vicinity of i cm⁻¹.

The amorphous silicon germanium or proto-crystalline silicon germanium of the first sub-layer 131 is not measured by Raman spectroscopy. Therefore, the crystal volume fraction of the first sub-layer 131 is 0 according to the above-mentioned equation. With regard to the nano-crystalline silicon material of the second sub-layer 133, since a crystal volume fraction greater than 0 is obtained by the above-mentioned equation, the crystal volume fraction of the second sub-layer 133 is greater than the crystal volume fraction of the first sub-layer 131. Moreover, regarding to the triple junction tandem photovoltaic device, the first sub-layer 131 of the bottom cell adjacent to the middle cell on which light is incident prior to the bottom cell also includes germanium as well. The second sub-layer 133 of the bottom cell is composed of amorphous silicon or has a crystal volume fraction greater than the crystal volume fraction of the first sub-layer 131.

In the sub-layer combination numbered 18 in FIG. 10, since the first sub-layer 131 includes germanium which prevents crystallization and the second sub-layer 133 is composed of nano-crystalline silicon, the crystal volume fraction of the second sub-layer 133 is greater than the crystal volume fraction of the first sub-layer 131.

In the sub-layer combination numbered 19 in FIG. 10, since the first sub-layer 131 includes proto-crystalline material as well as germanium preventing crystallization and the second sub-layer 133 is composed of nano-crystalline silicon germanium, the crystal volume fraction of the second sub-layer 133 is greater than the crystal volume fraction of the first sub-layer 131.

The hydrogen dilution ratio of silicon-containing gas and hydrogen gas supplied to each process chamber group in addition to gas including non-silicon element is constant.

As mentioned, when the intrinsic semiconductor layer 130a to 130c including the plurality of the sub-layers 131 and 133 is formed, a degradation rate, i.e., a difference between an initial efficiency and a stabilized efficiency, is reduced. Therefore, the photovoltaic device manufactured according to the embodiment of the present invention can have a high stabilized efficiency.

That is, the first sub-layer 131 prevents the columnar growth of the crystalline silicon grain of the second sub-layer 133. Unlike the embodiment of the present invention, as shown in FIG. 9, when the intrinsic semiconductor layer is composed of nothing but proto-crystalline silicon, the size of the crystalline silicon grain G increases as a process of deposition proceeds, so that the crystalline silicon grain exhibits a columnar growth.

The columnar growth of the crystalline silicon grain increases the carrier recombination rate of an electron and hole in a grain boundary. Also, a time required for the efficiency of the photovoltaic device to reach the stabilized efficiency is increased due to the non-uniform size of the crystalline silicon grain, and the stabilized efficiency is also degraded.

On the contrary to this, with regard to the intrinsic semiconductor layer 130a to 130c including the plurality of the sub-layers 131 and 133 as described in the embodiment of the present invention, short-range-order (SRO) and medium-range-order (MRO) are improved, so that the intrinsic semiconductor layer 130a to 130c is rapidly degraded and the stabilized efficiency becomes higher. Since the first sub-layer 131 prevents the columnar growth of the crystalline silicon grain, a time required for the efficiency of the photovoltaic device to reach the stabilized efficiency is reduced and the stabilized efficiency becomes higher.

The crystalline silicon grains of the second sub-layer 133 are surrounded by the amorphous silicon material or grain boundary, and consequently are separated from each other. The separated crystalline silicon grain functions as a core of radioactive recombination of some captured carriers, and so prevents photo-creation of a dangling bond. This reduces non-radioactive recombination of the amorphous silicon material, which surrounds the crystalline silicon grains, of the second sub-layer 133.

The sub-layers which are alternately stacked and have different refractive indices function as a waveguide respectively and enhance internal reflection, so that light trapping increases. The crystalline silicon grain of the second sub-layer 133 forms a texturing structure on the surface of the intrinsic semiconductor layer, thereby improving light scattering effect.

The diameter of the crystalline silicon grain of the second sub-layer 133 formed through combinations numbered from 1 to 11 in FIG. 10 is equal to or larger than 3 nm and equal to or smaller than 10 nm. It is difficult to form the crystalline silicon grain having a size smaller than 3 nm and degradation rate reduction effect of the photovoltaic device is deteriorated. When the size of the crystalline silicon grain is larger than 10 nm, the volume of the grain boundary surrounding the crystalline silicon grain is excessively increased, so that the carrier recombination is increased as well and efficiency may decrease.

The sub-layers derived from combinations numbered from 1 to 11 in FIG. 10 are formed by introducing hydrogen gas and silicon-containing gas or by introducing not only hydrogen gas and silicon-containing gas but also gas including oxygen, carbon or nitrogen. As a result, the first sub-layer 131 of the intrinsic semiconductor layer of the top cell is composed of amorphous silicon material. The second sub-layer 133 is composed of proto-crystalline silicon material. Here, the optical band gap of the intrinsic semiconductor layer of the top cell is equal to or larger than 1.85 eV and equal to or smaller than 2.0 eV.

When the optical band gap of the intrinsic semiconductor layer of the top cell is equal to or larger than 1.85 eV, the top cell can absorb light with a short wavelength having a high energy density. When the optical band gap of intrinsic semiconductor layer of the top cell is larger than 2.0 eV, the intrinsic semiconductor layer 130a to 130c including the plurality of the sub-layers 131 and 133 are difficult to form and light absorption is reduced. Accordingly, short-circuit current is reduced and efficiency is degraded.

A multi junction photovoltaic device includes photoelectric conversion layers including the first conductive semiconductor layer 120a to 120c, the intrinsic semiconductor layer 130a to 130c and the second conductive semiconductor layer 140a to 140c. Here, the top cell is a photoelectric conversion layer on which light is first incident among the plurality of the photoelectric conversion layers.

The sub-layers derived from combinations numbered from 12 to 17 in FIG. 10 are formed by introducing not only hydrogen gas and silicon-containing gas but also gas including germanium. The optical band gap of the bottom cell of the double junction photovoltaic device or the middle cell of the triple junction photovoltaic device is equal to or larger than 1.2 eV and equal to or smaller than 1.7 eV. When the optical band gap is equal to or larger than 1.2 eV and equal to or smaller than 1.7 eV, the deposition rate of the intrinsic semiconductor layer 130a to 130c is prevented from being rapidly reduced and dangling bond density and recombination are reduced. Therefore, efficiency is prevented from being degraded.

The sub-layers derived from combinations numbered from 18 to 19 in FIG. 10 are also formed by also introducing hydrogen gas, silicon-containing gas and gas including germanium. The optical band gap of the bottom cell of the triple junction photovoltaic device is equal to or larger than 0.9 eV and equal to or smaller than 1.2 eV. When the optical band gap is equal to or larger than 0.9 eV and equal to or smaller than 1.2 eV, it is possible to effectively absorb light with a long wavelength other the wavelength range absorbed by the top cell and middle cell.

The average hydrogen content of the intrinsic semiconductor layer including the first sub-layer 131 and the second sub-layer 133, all of which are formed through combinations numbered from 1 to 19 in FIG. 10 is equal to or more than 15 atomic % and equal to or less than 25 atomic %. When the average hydrogen content of the intrinsic semiconductor layer 130a to 130c is less than 15 atomic %, the optical band gap of the intrinsic semiconductor layer 130a to 130c is small and dangling bonds are increased, so that the degradation rate may be increased. When the average hydrogen content of the intrinsic semiconductor layer 130a to 130c is more than 25 atomic %, the optical band gap becomes too large and photosensitivity is reduced, so that the amount of electric current decreases.

The average oxygen content, average carbon content or average nitrogen content of the intrinsic semiconductor layer of the top cell formed through combinations numbered from 1 to 11 in FIG. 10 is more than 0 atomic % and equal to or less than 3 atomic %. When the average oxygen content, average carbon content or average nitrogen content of the intrinsic semiconductor layer 130a to 130c is more than 3 atomic %, the optical band gap of the intrinsic semiconductor layer 130a to 130c rapidly increases and dangling bond density rapidly increases. Accordingly, short-circuit current and fill factor (FF) are reduced, so that the efficiency is degraded.

The average germanium content of the intrinsic semiconductor layer formed through the sub-layer combinations numbered from 12 to 19 in FIG. 10 is more than 0 atomic % and equal to or less than 30 atomic %. When the average germanium content of the intrinsic semiconductor layer 130a to 130c is more than 30 atomic %, the deposition rate of the intrinsic semiconductor layer 130a to 130c is rapidly reduced and the carrier recombination is increased due to the increase of the dangling bond density, so that the short-circuit current, fill factor (FF) and efficiency are reduced.

When the second sub-layer 133 is composed of nano-crystalline silicon based material like in the sub-layer combinations numbered from 15 to 17 in FIG. 10, the average crystal volume fraction of the second sub-layer 133 is equal to or greater than 16% and the average crystal volume fraction of the intrinsic semiconductor layer is equal to or greater than 8% and is less than 30%. When the average crystal volume fraction of the second sub-layer 133 is equal to or greater than 16%, the peak of the crystalline silicon grain can be detected by Raman spectroscopy. When the average crystal volume fraction of the intrinsic semiconductor layer is equal to or greater than 8%, the crystalline silicon grain is fully formed and the minimum thickness of the second sub-layer 133 can be guaranteed. When the average crystal volume fraction of the intrinsic semiconductor layer is less than 30%, the crystallinity is prevented from being excessively increased, so that the optical band gap is prevented from being excessively reduced due to the increase of recombination.

When the second sub-layer 133 is composed of nano-crystalline silicon material like in the sub-layers combination numbered 18 in FIG. 10, the average crystal volume fraction of the second sub-layer 133 is equal to or greater than 16% and the average crystal volume fraction of the intrinsic semiconductor layer is equal to or greater than 30% and is equal to or less than 80%. When the average crystal volume fraction of the intrinsic semiconductor layer is equal to or greater than 30%, an amorphous incubation film is reduced and the carrier recombination is prevented from increasing. When the average crystal volume fraction of the intrinsic semiconductor layer is equal to or less than 80%, the recombination in the grain boundary is prevented from increasing.

When the second sub-layer 133 is composed of nano-crystalline silicon material like in the sub-layer combination numbered 19 in FIG. 10, the average crystal volume fraction of the second sub-layer 133 is equal to or greater than 16% and the average crystal volume fraction of the intrinsic semiconductor layer is equal to or greater than 8% and is less than 30%.

The average oxygen content of the intrinsic semiconductor layer formed through combinations numbered from 1 to 19 in FIG. 10 is more than 0 and equal to or less than 1.0×10²⁰ atoms/cm³. When the average oxygen content of the intrinsic semiconductor layer 130a to 130c is more than 1.0×10²⁰ atoms/cm³, photovoltaic conversion efficiency decreases.

In the embodiment of the present invention, the first sub-layer 131 is formed prior to the second sub-layer 133. However, the second sub-layer 133 may be formed prior to the first sub-layer 131.

As described above, in the method for manufacturing the photovoltaic device according to the embodiment of the present invention, the process condition of each of the process chamber groups is maintained constant and the process conditions of adjacent process chamber groups are different from each other. As a result, the process condition of each of the process chamber groups is maintained constant, so that it is possible to stably form a sub-layer and to form a sub-layer including the crystalline silicon grains. For example, when the flow rates of the gases change at the time of forming the sub-layer within the process chamber, turbulence is created due to the gas flow rate change, so that the sub-layer may not be formed stably. In the mean time, since the flow rate within the process chamber is maintained constant in the present invention, the sub-layer can be stably formed.

As such, the process condition of each of the process chamber groups is maintained constant. Accordingly, the thicknesses of the plurality of the first sub-layers 131 may be the same as each other and the thicknesses of the plurality of the second sub-layers 133 may be the same as each other.

While the embodiment of the present invention has been described with reference to the accompanying drawings, it can be understood by those skilled in the art that the present invention can be embodied in other specific forms without departing from its spirit or essential characteristics. Therefore, the foregoing embodiments and advantages are merely exemplary and are not to be construed as limiting the present invention. The present teaching can be readily applied to other types of apparatuses. The description of the foregoing embodiments is intended to be illustrative, and not to limit the scope of the claims. Many alternatives, modifications, and variations will be apparent to those skilled in the art. In the claims, means-plus-function clauses are intended to cover the structures described herein as performing the recited function and not only structural equivalents but also equivalent structures.

What is claimed is:

1. A method for manufacturing a photovoltaic device including a substrate; a first electrode and a second electrode which are placed over the substrate; a first conductive semiconductor layer, an intrinsic semiconductor layer including a first sub-layer and a second sub-layer, and a second conductive semiconductor layer, which are placed between the first electrode and the second electrode, the method comprising:
forming the first sub-layer having a first crystal volume fraction in an ‘i’-th process chamber group (‘i’ is a natural number equal to or greater than 1) among a plurality of process chamber groups; and
forming the second sub-layer in an ‘i+1’-th process chamber group among the plurality of the process chamber groups, the second sub-layer contacting with the first sub-layer, including crystalline silicon grains and having a second crystal volume fraction greater than the first crystal volume fraction.

2. A method for manufacturing a photovoltaic device including a substrate; a first electrode and a second electrode which are placed over the substrate; a first conductive semiconductor layer, an intrinsic semiconductor layer and a second conductive semiconductor layer, which are placed between the first electrode and the second electrode, the method comprising:
maintaining constant, in an ‘i’-th process chamber group (‘i’ is a natural number equal to or greater than 1) among a plurality of process chamber groups, a first process condition for forming a first sub-layer of the intrinsic semiconductor layer during the formation of the first sub-layer; and
maintaining constant, in an ‘i+1’-th process chamber group among the plurality of the process chamber groups, a second process condition different from the first process condition and for forming a second sub-layer of the intrinsic semiconductor layer during the formation of the second sub-layer contacting with the first sub-layer and including crystalline silicon grains.

3. The method of claim 2, wherein the process chamber group comprises at least one process chamber.

4. The method of claim 2, wherein the substrate is a flexible substrate.

5. The method of claim 2, wherein the first process condition and the second process condition comprise one of a hydrogen dilution ratio of hydrogen gas and silicon-containing gas introduced into the process chamber group, a frequency of voltage supplied to the process chamber group, a temperature within the process chamber group, and a flow rate of gas including non-silicon element, which is introduced into the process chamber group, and plasma discharge power.

6. The method of claim 2, wherein a hydrogen dilution ratio of hydrogen gas and silicon-containing gas introduced into the ‘i’-th process chamber group is less than a hydrogen dilution ratio of hydrogen gas and silicon-containing gas introduced into the ‘i+1’-th process chamber group.

7. The method of claim 6, wherein flow rates of hydrogen gas introduced into the ‘i’-th and the ‘i+1’ process chamber groups are constant.

8. The method of claim 6, wherein a process pressure within the ‘i’-th process chamber group is greater than a process pressure within the ‘i+1’-th process chamber group.

9. The method of claim 2, wherein a frequency of voltage supplied to the ‘i’-th process chamber group is lower than a frequency of voltage supplied to the ‘i+1’-th process chamber group.

10. The method of claim 9, wherein the frequency of the voltage supplied to the ‘i’-th process chamber group is equal to or higher than 13.56 MHz, and the frequency of the voltage supplied to the ‘i+1’-th process chamber group is equal to or higher than 27.12 MHz.

11. The method of claim 2, wherein a temperature of the ‘i’-th process chamber group is higher than a temperature of the ‘i+1’-th process chamber group.

12. The method of claim 2, wherein a plasma discharge power of the ‘i’-th process chamber group is higher than a plasma discharge power of the ‘i+1’-th process chamber group.

13. The method of claim 5, wherein the non-silicon element comprises oxygen, carbon, nitrogen or germanium.

14. The method of claim 2, wherein a flow rate of gas including non-silicon element, which is introduced into the ‘i’-th process chamber group, is greater than a flow rate of gas including non-silicon element, which is introduced into the ‘i+1’-th process chamber group.

15. The method of claim 2, wherein a flow rate of gas including non-silicon element, which is introduced into each of the process chamber groups in which the first sub-layer or the second sub-layer is formed, is constant, wherein flow rates of the gas introduced into the process chamber groups in which the second sub-layer is formed are less than flow rates of the gas introduced into the process chamber group in which the first sub-layer is formed, and wherein either the first sub-layer or the second sub-layer is formed such that the closer it is to a light incident side, the larger an optical band gap is.

16. The method of claim 15, wherein an n-type semiconductor layer, the intrinsic semiconductor layer and a p-type semiconductor layer are sequentially stacked on the substrate, wherein the gas comprises oxygen, carbon, or nitrogen, and wherein a flow rate of the gas introduced into the ‘i’-th process chamber group is less than a flow rate of the gas introduced into an ‘i+2’-th process chamber group.

17. The method of claim 15, wherein an n-type semiconductor layer, the intrinsic semiconductor layer and a p-type semiconductor layer are sequentially stacked on the substrate, wherein the gas comprises oxygen, carbon, or nitrogen, and wherein a flow rate of the gas introduced into the ‘i+1’-th process chamber group is less than a flow rate of the gas introduced into an ‘i+3’-th process chamber group.

18. The method of claim 15, wherein an n-type semiconductor layer, the intrinsic semiconductor layer and a p-type semiconductor layer are sequentially stacked on the substrate, wherein the gas comprises germanium, and wherein a flow rate of the gas introduced into the ‘i’-th process chamber group is greater than a flow rate of the gas introduced into an ‘i+2’-th process chamber group.

19. The method of claim 15, wherein an n-type semiconductor layer, the intrinsic semiconductor layer and a p-type semiconductor layer are sequentially stacked on the substrate, wherein the gas comprises germanium, and wherein a flow rate of the gas introduced into the ‘i+1’-th process chamber group is greater than a flow rate of the gas introduced into an ‘i+3’-th process chamber group.

20. The method of claim 15, wherein a p-type semiconductor layer, the intrinsic semiconductor layer and an n-type semiconductor layer are sequentially stacked on the substrate, wherein the gas comprises oxygen, carbon, or nitrogen, and wherein a flow rate of the gas introduced into the ‘i’-th process chamber group is greater than a flow rate of the gas introduced into an ‘i+2’-th process chamber group.

21. The method of claim 15, wherein a p-type semiconductor layer, the intrinsic semiconductor layer and an n-type semiconductor layer are sequentially stacked on the substrate, wherein the gas comprises oxygen, carbon, or nitrogen, and wherein a flow rate of the gas introduced into the ‘i+1’-th process chamber group is greater than a flow rate of the gas introduced into an ‘i+3’-th process chamber group.

22. The method of claim 15, wherein a p-type semiconductor layer, the intrinsic semiconductor layer and an n-type semiconductor layer are sequentially stacked on the substrate, wherein the gas comprises germanium, and wherein a flow rate of the gas introduced into the ‘i’-th process chamber group is less than a flow rate of the gas introduced into an ‘i+2’-th process chamber group.

23. The method of claim 15, wherein a p-type semiconductor layer, the intrinsic semiconductor layer and an n-type semiconductor layer are sequentially stacked on the substrate, wherein the gas comprises germanium, and wherein a flow rate of the gas introduced into the ‘i+1’-th process chamber group is less than a flow rate of the gas introduced into an ‘i+3’-th process chamber group.

24. A photovoltaic device comprising:
a substrate;
a first electrode and second electrode which are placed over the substrate; and
a plurality of photoelectric conversion layers placed between the first electrode and the second electrode,
wherein an intrinsic semiconductor layer of a photoelectric conversion layer that is the closest to a light incident side among the plurality of the photoelectric conversion layers comprises a first sub-layer composed of amorphous silicon based material and a second sub-layer including crystalline silicon grains.

25. A photovoltaic device comprising:
a substrate;
a first electrode and second electrode which are placed over the substrate; and
a plurality of photoelectric conversion layers placed between the first electrode and the second electrode,
wherein an intrinsic semiconductor layer of a photoelectric conversion layer, which is adjacent to a photoelectric conversion layer on which light is incident prior to the photoelectric conversion layer among the plurality of the photoelectric conversion layers, comprises a first sub-layer including germanium and a second sub-layer which is composed of amorphous silicon or has a crystal volume fraction greater than a crystal volume fraction of the first sub-layer.

26. The photovoltaic device of claim 25, wherein, when the adjacent photoelectric conversion layer is a bottom cell of a double junction tandem photovoltaic device or a middle cell of a triple junction tandem photovoltaic device, the first sub-layer comprises hydrogenated amorphous silicon germanium or hydrogenated proto crystalline silicon germanium, and the second sub-layer is composed of hydrogenated nano-crystalline silicon material or hydrogenated proto-crystalline silicon material including crystalline silicon grains.

27. The photovoltaic device of claim 25, wherein, when the adjacent photoelectric conversion layer is a bottom cell of a triple junction tandem photovoltaic device, the first sub-layer comprises hydrogenated proto-crystalline germanium or hydrogenated nano-crystalline germanium, and the second sub-layer comprises hydrogenated nano-crystalline silicon based material.

28. The photovoltaic device of claim 24, wherein an optical band gap of the intrinsic semiconductor layer of the photoelectric conversion layer that is the closest to the light incident side is equal to or larger than 1.85 eV and equal to or smaller than 2.0 eV.

29. The photovoltaic device of claim 25, wherein, when the adjacent photoelectric conversion layer is a bottom cell of a double junction tandem photovoltaic device or a middle cell of a triple junction tandem photovoltaic device, an optical band gap of the intrinsic semiconductor layer of the adjacent photoelectric conversion layer is equal to or larger than 1.2 eV and equal to or smaller than 1.7 eV.

30. The photovoltaic device of claim 25, wherein, when the adjacent photoelectric conversion layer is a bottom cell of a triple junction tandem photovoltaic device, an optical band gap of the intrinsic semiconductor layer of the adjacent photoelectric conversion layer is equal to or larger than 0.9 eV and equal to or smaller than 1.2 eV.

31. The photovoltaic device of claim 25, wherein an average hydrogen content of the intrinsic semiconductor layer is equal to or more than 15 atomic % and equal to or less than 25 atomic %.

32. The photovoltaic device of claim 24, wherein an average oxygen content, average carbon content or average nitrogen content of the intrinsic semiconductor layer of the photoelectric conversion layer that is the closest to the light incident side is more than 0 atomic % and equal to or less than 3 atomic %.

33. The photovoltaic device of claim 25, wherein an average germanium content of the intrinsic semiconductor layer of the adjacent photoelectric conversion layer is more than 0 atomic % and equal to or less than 30 atomic %.

34. The photovoltaic device of claim 25, wherein, when the adjacent photoelectric conversion layer is a bottom cell of a double junction tandem photovoltaic device or a middle cell of a triple junction tandem photovoltaic device, and when the second sub-layer is composed of hydrogenated nano-crystalline silicon or hydrogenated nano-crystalline silicon germanium, an crystal volume fraction of the second sub-layer is equal to or greater than 16% and an average crystal volume fraction of the intrinsic semiconductor layer of the adjacent photoelectric conversion layer is equal to or greater than 8% and is less than 30%.

35. The photovoltaic device of claim 25,
wherein, when the adjacent photoelectric conversion layer is a bottom cell of a triple junction tandem photovoltaic device, and when the second sub-layer is composed of hydrogenated nano-crystalline silicon,
a crystal volume fraction of the second sub-layer is equal to or greater than 16% and an average crystal volume fraction of the intrinsic semiconductor layer of the adjacent photoelectric conversion layer is equal to or greater than 30% and is equal to or less than 80%,
and wherein, when the adjacent photoelectric conversion layer is a bottom cell of a triple junction tandem photovoltaic device, and when the second sub-layer is composed of hydrogenated nano-crystalline silicon germanium,
a crystal volume fraction of the second sub-layer is equal to or greater than 16% and an average crystal volume fraction of the intrinsic semiconductor layer of the adjacent photoelectric conversion layer is equal to or greater than 8% and less than 30%.

36. The photovoltaic device of claim 25, wherein an average oxygen content of the intrinsic semiconductor layer is equal to or less than 1.0×10²⁰ atoms/cm³.

37. The photovoltaic device of claim 24, wherein a diameter of the crystalline silicon grain is equal to or larger than 3 nm and equal to or smaller than 10 nm.

38. The photovoltaic device of claim 26, wherein, when the second sub-layer is composed of hydrogenated proto-crystalline silicon based material, a diameter of the crystalline silicon grain is equal to or larger than 3 nm and equal to or smaller than 10 nm, and wherein, when the second sub-layer is composed of hydrogenated nano-crystalline silicon material, a diameter of the crystalline silicon grain is equal to or larger than 20 nm and equal to or smaller than 100 nm.

39. The photovoltaic device of claim 25, wherein the intrinsic semiconductor layer comprises a plurality of the first sub-layers and a plurality of the second sub-layers, and thicknesses of the plurality of the first sub-layers are the same as each other and thicknesses of the plurality of the second sub-layers are the same as each other.
